(19) United States
(12) Patent Application Publication
(10) Pub. No.: US 2011/0147817 A1
(43) Pub. Date: Jun. 23, 2011

(54) SEMICONDUCTOR COMPONENT HAVING AN OXIDE LAYER

(75) Inventors: Hans-Joachim Schulze, Taufkirchen (DE); Helmut Strack, Munich (DE); Hans Weber, Bayerisch Gmain (DE)

(73) Assignee: INFINEON TECHNOLOGIES AUSTRIA AG, Villach (AT)

(21) Appl. No.: 12/640,974

(22) Filed: Dec. 17, 2009

(51) Int. Cl. H01L 29/78; H01L 29/02; H01L 21/336; H01L 21/02

(52) U.S. Cl. 257/296; 257/649; 438/589; 438/597; 257/E29.256; 257/E29.002; 257/E21.409; 257/E21.002

(57) ABSTRACT

Semiconductor component having an oxide layer. One embodiment includes a first semiconductor region and a second semiconductor region. An oxide layer is arranged between the first and second semiconductor region. The first semiconductor region and the oxide layer form a first semiconductor-oxide interface. The second semiconductor region and the oxide layer form a second semiconductor-oxide interface. The oxide layer has a chlorine concentration, the chlorine concentration having a first maximum in the region of the first semiconductor-oxide interface, and having a second maximum in the region of the second semiconductor-oxide interface.

### TECHNICAL FIELD

The present disclosure relates to a semiconductor component having an oxide layer, in particular a thermally grown oxide layer arranged in a semiconductor body, and to methods for forming such semiconductor component.

### BACKGROUND

Oxide layers, such as thermally grown oxide layers, are widely-used in semiconductor components. They are used to form gate dielectrics in MOS transistors, such as MOSFET or IGBT, or to form an insulation layer between two semiconductor layers in an SOI substrate. In one type of MOS transistor an oxide layer is arranged between two usually monocrystalline semiconductor regions, the transistor's drift zone and a drift control zone. The drift control zone generates a conducting accumulation or inversion channel in the drift zone along the oxide layer whenever the transistor is in an on-state. This results in a lower on-resistance compared with MOS transistors not having a drift control zone.

A thermally grown semiconductor oxide, such as a silicon oxide, usually includes electrical charges resulting from the production process. These charges may include: interface trapped charges that are trapped at the interface between the oxide layer and the adjoining semiconductor material; fixed positive oxide charges in the oxide layer; mobile ionic charges, such as charges resulting from alkali ions Ni+, Na+, K+ that are present in the oxide; and oxide trapped charges.

These oxide charges may influence the electrical properties of the semiconductor component. In MOS transistors having a drift zone and a drift control zone separated from the drift zone by an oxide layer oxide charges may significantly reduce the transistor's voltage blocking capability. When the components blocks (is in its off-state) a space charge region propagates in the active semiconductor volume formed by the drift zone in the drift zone starting from a pn-junction between the drift zone and a zone, such as a body zone, doped complementarily to the drift zone.

The space charge zone also propagates in the drift control zone. The space charge region is associated with an electrical field resulting, e.g., from charges in the drift zone, i.e. on the one side of the pn-junction, and from charges in the complementarily doped zone, i.e. on the other side of the pn-junction. An avalanche breakthrough sets in when the electrical field strength reaches a critical value (Ecrit). The voltage blocking capability of a semiconductor component is dependent on the number of charges in the active semiconductor volume. Generally—if no additional measures are taken—the voltage blocking capability increases with a decreasing doping concentration of the active volume. In this connection oxide charges in the oxide layer adjacent to the drift zone act like dopant charges and may therefore influence the voltage blocking capability negatively.

For these and other reasons there is need for the present invention.

### BRIEF DESCRIPTION OF THE DRAWINGS

Embodiments will now be explained with reference to the accompanying drawings. These drawings serve to explain a basic principle, so that only features necessary for understanding the basic principle are illustrated. The drawings are not to scale. Like reference characters designate like features throughout the drawings.

FIG. 1 schematically illustrates a cross section through one embodiment of a semiconductor device including a semiconductor component having a first and a second semiconductor region and a chlorine containing oxide layer arranged between the semiconductor regions.

FIG. 2 illustrates the chlorine concentration in the oxide layer according to an example of one embodiment.

FIGS. 3A-3B schematically illustrate one embodiment of a method of making a semiconductor including producing an oxide layer between two semiconductor regions.

FIG. 4 schematically illustrates a cross section through one embodiment of a semiconductor component having a barrier layer covering an oxide layer.

FIG. 5A-5C schematically illustrate another embodiment of a method for producing a semiconductor including an oxide layer between two semiconductor regions.

FIG. 6 schematically illustrates a cross section through one embodiment of a semiconductor component having oxide layers between drift zones and drift control zones.

FIG. 7 schematically illustrates a cross section through a part of an embodiment of the semiconductor component of FIG. 6.

### DETAILED DESCRIPTION OF THE DRAWINGS

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide a semiconductor device including a semiconductor component with oxide layers having reduced oxide charges and being long-term stable.

One embodiment of the present disclosure relates to a semiconductor component including: a first semiconductor region and a second semiconductor region; an oxide layer arranged between the first and second semiconductor region, first semiconductor region and the oxide layer forming a first semiconductor-oxide interface, and second semiconductor region and the oxide layer forming a second semiconductor-oxide interface. The oxide layer has a chlorine concentration, the chlorine concentration having a first maximum in the region of the first semiconductor-oxide interface, and having a second maximum in the region of the second semiconductor-oxide interface.

Another embodiment relates to a method for forming a semiconductor component, the method including: providing a semiconductor body having a first surface; forming at least one trench extending from the surface into the semiconductor body, the trench having trench surfaces; forming an oxide layer in the trench by thermally oxidizing the semiconductor body along the trench surfaces in the presence of chlorine.

Another embodiment relates to a method for forming a semiconductor component, the method including: providing a first semiconductor body having a first surface; forming an oxide layer having a chlorine concentration on the first surface by thermally oxidizing the first semiconductor body along the first surface in the presence of chlorine, the first semiconductor body and the oxide layer forming a first semiconductor-oxide interface; bonding a second semiconductor body layer on the oxide layer, the second semiconductor body and the oxide layer forming a second semiconductor-oxide interface; heating the arrangement including the first and second semiconductor body and the oxide layer, temperature and duration of the heating process being selected such that a first and a second maximum of a chlorine concentration of the oxide layer occurs in the region of the first and second semiconductor-oxide interface.

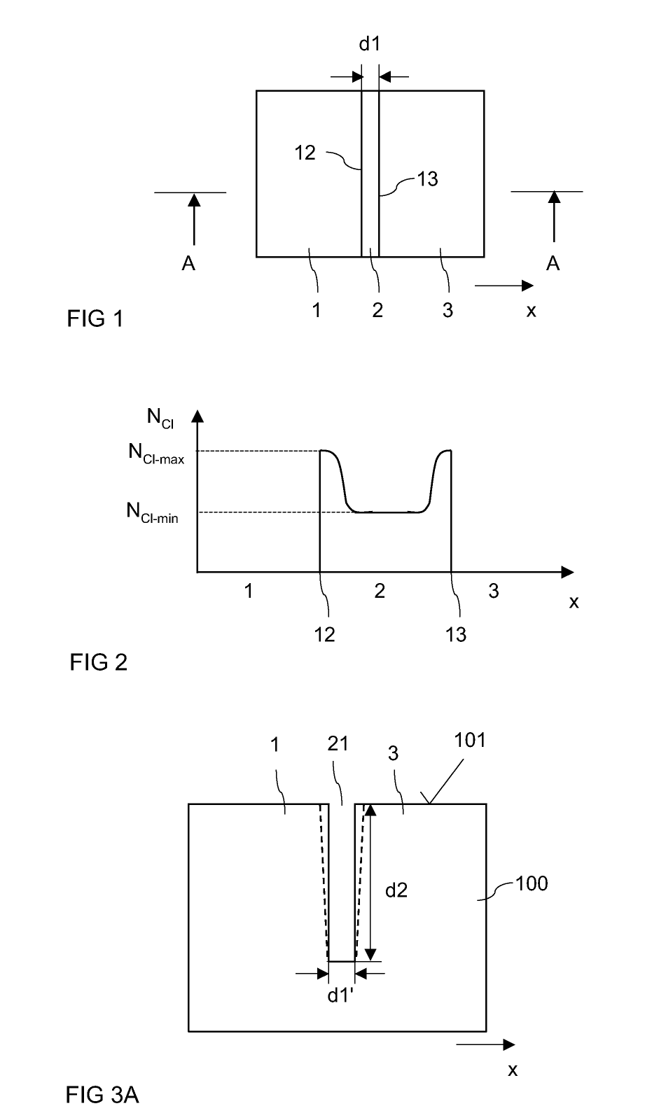

FIG. 1 schematically illustrates one embodiment of a semiconductor, including a cross section through a part of a semiconductor component. The semiconductor component includes two semiconductor regions 1, 3, and an oxide layer 2 arranged between the two semiconductor regions 1, 3. Semiconductor regions 1, 3 are, for example, monocrystalline semiconductor regions of silicon, or of another semiconductor material. According to one embodiment semiconductor regions 1, 3 are either n-doped or p-doped. According to another embodiment these semiconductor regions are non-doped (intrinsic).

Oxide layer 2 is a thermally grown oxide layer, such as a silicon oxide layer. The first semiconductor region 1 and the oxide layer 2 form a first semiconductor-oxide interface 12, and the second semiconductor region 3 and the oxide layer 2 form a second semiconductor-oxide interface 13.

The oxide layer 2 has a chlorine concentration. FIG. 2, illustrates one embodiment of a chlorine concentration NCl of the oxide layer 2 in a section plane A-A (see FIG. 1) and in a direction x perpendicular to the semiconductor-oxide interfaces 12, 13, the chlorine concentration NCl has two maxima: a first maximum in the region of the first semiconductor-oxide interface 12, and a second maximum in the region of the second semiconductor-oxide interface 13. The maximum chlorine concentration NCl-max, i.e. the maximum concentration of chlorine atoms, is, for example, in the range of between 1019 cm−3 and 2.1021 cm−3. A minimum chlorine concentration NCl-min is, for example in the range of between 1015 cm−3 and 1018 cm−3, and is in one embodiment in the range of between 1017 cm−3 and 1018 cm−3.

An oxide layer having two maxima of the chlorine concentration is, in particular, relevant in components that have active component areas adjacent to both sides of the oxide layer. Embodiments of such components will be explained hereinbelow. “Active component areas” are e.g., drift or base zones of semiconductor components.

A thickness d1 of the oxide layer is, dependent on the specific application, in the range of 10 nm to 1 μm, and in one embodiment in the range of 20 nm to 120 nm. The thickness d1 of the oxide layer 2 is the dimension of the oxide layer 2 in a direction perpendicular to the semiconductor-oxide interfaces 12, 13. The oxide layer contains chlorine that reduces or eliminates the oxide charges present in the oxide layer 2. The chlorine, that has its concentration maxima in the region of the semiconductor-oxide interfaces 12, 13, reduces interface trapped charges that are present along the semiconductor-oxide interfaces 12, 13, and fixed oxide charges, that are present in the oxide layer 2 close to the interfaces 12, 13. The semiconductor material acts like a barrier for the chlorine atoms. Due to this and, due to the fact that the oxide layer 2 is arranged between two semiconductor regions 1, 3 the chlorine concentration in the oxide layer 2 is long-term stable, so that the positive effect of the chlorine concentration on the oxide charges is a long-time effect. In one embodiment, the semiconductor regions 1, 2 are monocrystalline semiconductor regions that were epitaxially grown. As chlorine atoms do not diffuse in monocrystalline semiconductor material, such as silicon, the chlorine distribution illustrated in FIG. 2 is long-term stable. This is different in structures in which a oxide layer adjoins a semiconductor region or semiconductor layer in the course of the manufacturing process only on one side (not illustrated). In such structures the chlorine, in particular during high-temperature processes, diffuses out of the oxide layer, so that there is no long-time neutralization effect on the oxide charges.

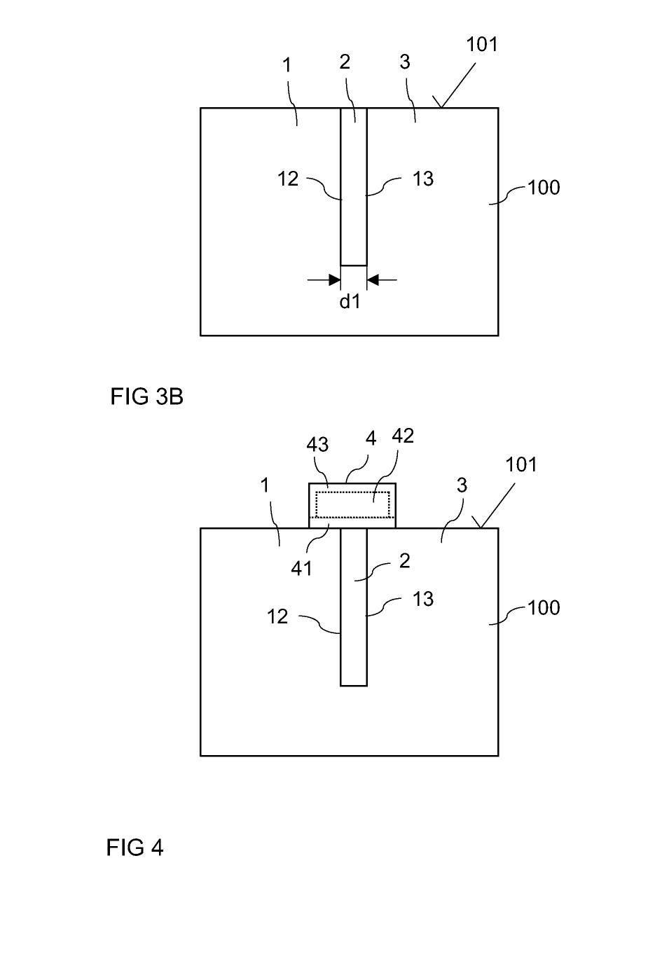

FIGS. 3A-3B schematically illustrate one embodiment of a method for making a semiconductor including producing a thermal oxide layer arranged between two semiconductor regions. Referring to FIG. 3A, this method includes forming a trench 21 in a semiconductor body 100. In the embodiment illustrated trench 21 extends starting from a first surface 101 of the semiconductor body 100 in a vertical direction of the semiconductor body 100. In this connection “the vertical direction” is the direction perpendicular to the first surface 101. Trench 21 has vertical sidewalls. However, this is only one embodiment, trench 21 could also have tapered sidewalls, so that a trench width d1′ increases in the direction of the first surface 101 (illustrated in dashed lines). In the horizontal plane, which is the plane of the first surface 101, trench 21 may have one of a number of different geometries, such as a line-shaped geometry, a rectangular geometry, a circular geometry, a hexagonal geometry, etc. A trench depth is, for example, in the range of between 10 μm and 200 μm. According to one embodiment the sidewalls have a <100>-crystal orientation.

In next processes steps, the result of which is illustrated in FIG. 3B, a thermal oxide 2 is grown by exposing the surfaces of the trench 21 to an oxidizing ambient. The oxidizing ambient is defined by its process gases and by its temperature. The temperature is, for example, in the range of between 600° C. and 1250° C., in one embodiment between 800° C. and 1000° C. The process gas contains oxygen, with the oxygen being either present as oxygen molecules (O2) or in water vapor (H2O). For obtaining a chlorine-containing oxide layer the process gas further includes chlorine, in one embodiment in the form of hydrochloric acid (HCl).

The concentration of chlorine in the chlorine-containing gas ranges between 1% and 8%, in particular between 2% and 4%, of the process gas. The percentage of the chlorine in the chlorine containing gas may be constant throughout the thermal oxidation process. In another embodiment the percentage of the chlorine in the chlorine-containing gas varies during the oxidation process. According to one embodiment no chlorine-containing gas is added to the process gas at the beginning of the thermal oxidation process, until a thin oxide layer has been produced on the surfaces of the trench 21. If, for example, hydrochloric acid gas is used as the chlorine-containing gas, then forming a thin oxide layer before adding the chlorine-containing gas protects the semiconductor material along the trench surfaces from being etched by the chlorine-containing gas. According to another embodiment the chlorine-containing gas is added to the process gas until the trench is completely filled. The duration of the oxidation process is dependent on the trench width, the oxidation process stops when trench 21 is completely filled.

In FIG. 3B oxide layer 2 is only arranged in the trench (21 in FIG. 3A) but not on the first surface 101. This may be obtained by first producing an oxide layer on the first surface 101 during the thermal oxidation process, and then removing the oxide layer from the first surface 101. The oxide layer may be removed from the first surface 101 by an etching and/or a chemical mechanical polishing process. According to another embodiment a protection layer (not illustrated) is formed on the first surface 101 that prevents a thermal oxide layer form being grown on the first surface 101.

The thickness d1 of the oxide layer 2 is different from the trench width d1′. This is due to the fact that during the thermal oxidation process semiconductor material is “consumed” at the surfaces of the trench in the chemical reaction that produces the semiconductor oxide layer 2 from the semiconductor material along the surfaces of the trench, and from the oxygen included in the process gas. Using silicon as the semiconductor material, a ratio d1′:d1 between the trench width d1′ and the layer thickness d1 of the resulting oxide is about 0.6:1.

The chlorine concentration illustrated in FIG. 2 having maxima in the region of the semiconductor-oxide interfaces 12, roughly 13 is independent of whether a chlorine-containing process gas is added throughout the complete thermal oxidation process, or not. During the oxidation process chlorine atoms that are included in the oxide layer drift in the direction of the semiconductor-oxide interfaces 12, 13 so that maxima of the chlorine concentration occur at these interfaces 12, 13, especially because chlorine atoms cannot diffuse into monocrystalline semiconductor layers, such as silicon layers, and because the interface between the oxide and the semiconductor material is an energetically preferred position of the chlorine atoms.

The manufacturing process of semiconductor components requires temperature processes, during which the semiconductor body of the component is heated to temperatures of up to 1000° C. and more. These temperature processes play an important role. These temperature processes are, for example, used for diffusing dopants into the semiconductor body, for activating implanted dopants, or for healing crystal damages resulting from implantation processes. In order to prevent chlorine atoms from diffusing out of the oxide layer 2 at the first surface 101, where the oxide layer 2 is not covered by a semiconductor material, a barrier may be arranged on the first surface 101 above the oxide layer 102. In one embodiment the trench depth d2 is much larger than the trench width d1′, in this case there is only a relatively small out-diffusion. According to one embodiment a ratio d2/d1′ between the trench depth d2 and the trench width d1′ is between 100 and 5000, with the trench depth d2 being in the range of between 10 μm and 30 μm, e.g., and with the trench width d1′ being in the range of between 20 nm and 120 nm, e.g.

FIG. 4 illustrates a cross section through a semiconductor component having a barrier 4 on the first surface 101 above the oxide layer 2. Barrier 4 at least partly covers the oxide layer 2 in those regions that are exposed in the region of the first surface 101. According to one embodiment barrier 4 completely covers oxide layer 2 on the first surface 101.

Barrier 4 is configured to prevent chlorine atoms from diffusing out of the oxide layer 2. For this, barrier 4 may include a nitride layer, such as a silicon nitride layer, or a silicon layer. According to another embodiment barrier 4 includes a layer stack having at least two layers of different materials. According to one embodiment (that is illustrated in dotted lines in FIG. 4) barrier 4 includes a layer stack having an oxide layer 41, a nitride layer 42 and a further oxide layer 43. Such layer stack will also be referred to as ONO stack (with 0 for oxide, and N for nitride) in the following.

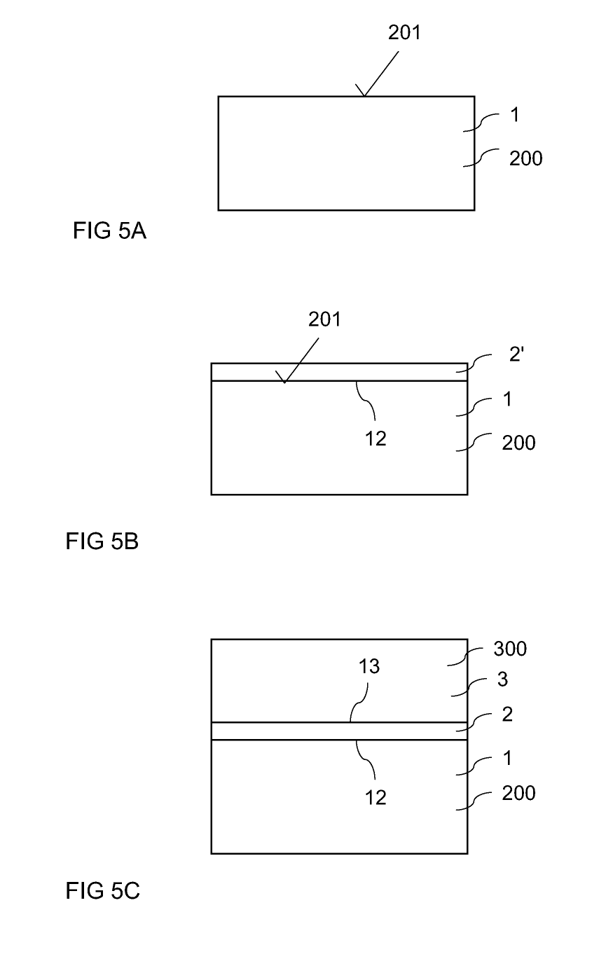

FIGS. 5A through 5C illustrate another embodiment of a method for making a semiconductor including producing a thermal oxide layer arranged between two semiconductor regions. Referring to FIG. 5A, a first semiconductor body 200 is provided, the first semiconductor body 200 forming a first semiconductor region 1.

Referring to FIG. 5B, an oxide layer 2′ is thermally grown on a first surface 201. Oxide layer 2′ is grown by exposing the first surface 201 of the first semiconductor body 200 to an oxidizing ambient in the presence of chlorine. The process parameters, i.e. the temperature and the composition of the process gas, as well as an optional variation of the temperature and the composition of the process gas during the oxidation process, may correspond to the parameters of the process that has been illustrated with reference to FIGS. 3A-3B.

Referring to FIG. 5C, a second semiconductor body 300 that forms a second semiconductor region 3, is bonded to that surface of the oxide layer 2′ facing away from the first semiconductor body 200. Bonding the second semiconductor body 300 to the oxide layer 2′ may, for example, involve: arranging the second semiconductor body 300 on top of the oxide layer 2′, and performing a temperature process, so as to bond the second semiconductor body 300 to the oxide layer 2′. The temperature of this temperature process is, for example, in the range of between 400° C. and 1250° C., in one embodiment between 900° C. and 1200°]. According to one embodiment the second semiconductor 300 has an optional thermally grown or deposited oxide layer on the side that is bonded to the oxide layer 2′, where this oxide layer may optionally include chlorine atoms.

Referring to the explanation hereinabove chlorine atoms diffuse out from the oxide layer in those regions that are not adjacent to or covered by a semiconductor region. Due to this effect the chlorine concentration of the oxide layer 2′ that is exposed at the surface facing away from the first semiconductor body 200 does not correspond to the chlorine concentration schematically illustrated in FIG. 2. The chlorine concentration of oxide layer 2′ has only one maximum, namely at the semiconductor-oxide interface 12 between the oxide layer 2′ and the semiconductor body 200. Further, due to the out—diffusion of a part of the chlorine atoms oxide layer 2′ has a lower dose of chlorine atoms in the oxide, compared to an oxide layer having two maxima.

In order to obtain a chlorine concentration characteristic as illustrated in FIG. 2 dependent on the temperature that is applied during the bonding process and dependent on the duration of the bonding temperature process optionally a further temperature process may be performed after bonding the second semiconductor body 300 to the oxide layer 2′. The temperature of this temperature process is, in one embodiment, in the range of between 700° C. and 1100° C., and the duration of thermal process is, in one embodiment, in the range of between one and a few hours. During this thermal process the chlorine atoms present in oxide layer 2′ are subject to drifting processes, that result in a redistribution of the chlorine atoms, and in an accumulation of the chlorine atoms in the region of both semiconductor-oxide interfaces 12, 13, with interface 13 according to FIG. 5C being the interface between the oxide layer 2 and the second semiconductor body 300. In other words: During the bond annealing process the diffusion mobility of the chlorine atoms present within the oxide layer 2′ is enhanced and a rearrangement of the chlorine distribution can take place. While the temperature ramp down phase of the annealing process the chlorine atoms are gettered at the interfaces 12 and 13 resulting in a chlorine concentration distribution according FIG. 2. Further temperature processes in the range between 700° C. and 1200° C. in a later stage of the manufacturing process can improve the chlorine redistribution additionally. As a consequence a chlorine concentration maximum is formed not only in the range of the interfaces 12 but, in difference to the situation before the annealing process, as well in the region of interface 13. Reference character 2 in FIG. 5C denotes the oxide layer after the end of the further temperature process, so that the oxide layer 2 according to FIG. 5C has a chlorine concentration characteristic according to FIG. 2.

It should be noted that FIGS. 5A-5C only schematically illustrate a section of a semiconductor arrangement having a first and a second semiconductor body 200, 300 and an oxide layer arranged between the semiconductor bodies 200, 300. In order to prevent chlorine atoms from diffusing out of the oxide layer 2 at those ends of the oxide layer that are not covered by one of the semiconductor bodies 200, 300 suitable barriers (not illustrated) may be arranged on the oxide layer 2 in these regions.

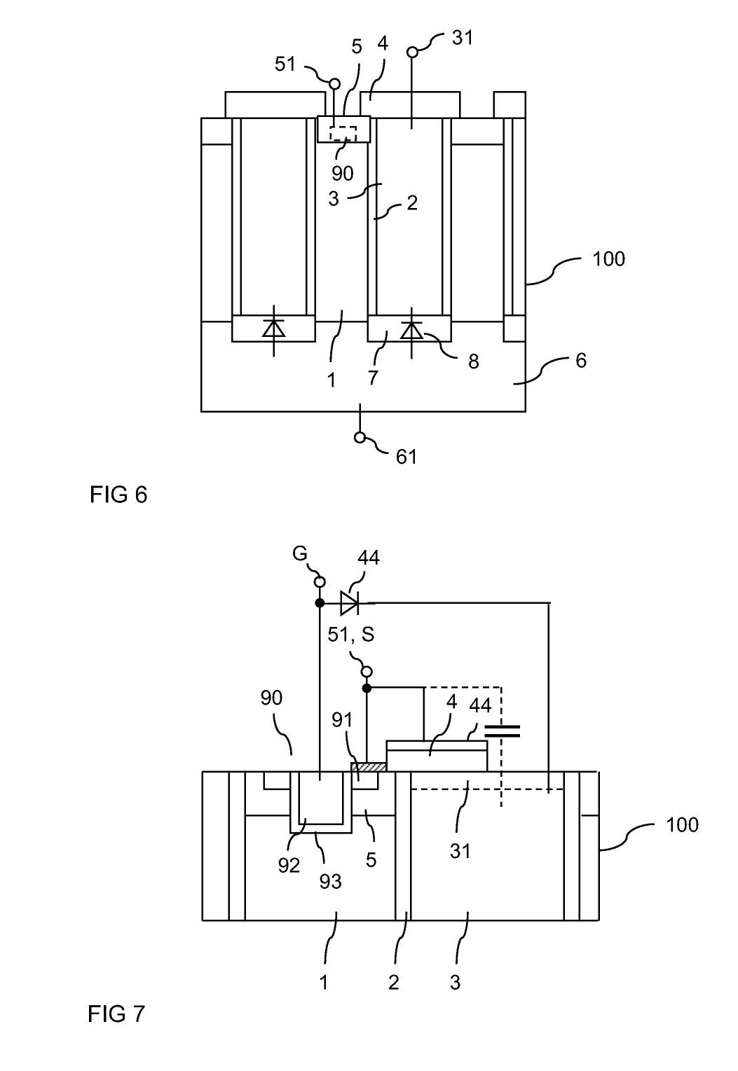

FIG. 6 schematically illustrates a cross section through a vertical semiconductor component having first and second semiconductor regions 1, 3 and a thermal oxide layer 2 arranged between the two semiconductor regions 1, 3. In the semiconductor component illustrated in FIG. 6 first semiconductor region 1 forms a drift zone, and second semiconductor region 3 forms a drift control zone, and oxide layer 2 forms a drift control zone dielectric. Drift zone 1 is arranged between a first and a second component zone 5, 6. One of a pn-junction and a Schottky-contact is formed between the drift zone 1 and one of the first and second component zones 5, 6.

According to one embodiment the semiconductor component is a Schottky diode. In this case one of the first and second component zones 5, 6, such as first component zone 5, is a Schottky-metal zone, and the other one of the first and second component zone 5, 6, such as the second component zone 6, is a semiconductor zone that has the same conductivity type as drift zone 1, but that is more highly doped than drift zone 1. The Schottky diode blocks, whenever a voltage is applied between terminals 51, 61 of the first and second component zones 5, 6 that biases the Schottky contact in a reverse direction, and the Schottky diode conducts, whenever a voltage is applied between terminals 51, 61 that biases the Schottky contact in a forward direction. In the on-state of the component an electrical potential is applied to the drift control zone 3 that is suitable to effect a conducting channel along the drift control zone dielectric 2 in the drift zone 1 between the first and second component zone 5, 6. This conducting channel significantly reduces the on-resistance of the component. In the off-state of the component a space charge region propagates in the drift zone 1 starting from the Schottky junction. Like drift zone 1 drift control zone 3 is of a monocrystalline semiconductor material, so that a space charge region also propagates in the drift control zone 3.

According to another embodiment the semiconductor component is a MOSFET. First component zone 5 is a body zone, and second component zone 6 is a drain zone of the semiconductor component. Besides body zone 5, drift zone 1 and drain zone 6 the semiconductor component has a control structure 90 arranged in the region of the body zone 5. Control structure 90 is only schematically illustrated (in dashed lines) in FIG. 6, and is illustrated in greater detail in FIG. 7.

Control structure 90 includes a source zone 91 arranged in the body zone 5 and separated from drift zone 2, and a gate electrode 92 having a gate terminal G. Gate electrode 92 is dielectrically insulated from source zone 91, body zone 5 and drift zone 1 and extends from the source zone 91 through body zone 5 into drift zone 1. In the embodiment illustrated in FIG. 7 gate electrode 92 is a trench electrode that is arranged in a trench of the semiconductor body. However, any other gate electrode structure, such as planar gate electrodes, may be used as well.

The MOSFET may be an n-type or p-type MOSFET, with the type being determined by the conductivity type of source and drain zones 91, 6. An n-type MOSFET has n-doped source and drain regions 91, 6, and a p-type MOSFET has p-doped source and drain regions 91, 6. Body zone 5 is complementary doped to source zone 91. Drift zone 1 is of the same doping type as source and drain zones 91, 6, or is complementarily doped to source and drain regions 91, 6. In the first case a pn-junction is formed between body zone 5 and drift zone 1, and in the second case a pn-junction is formed between drift zone 1 and drain zone 6. Starting from this pn-junction a space charge region propagates in the drift zone 1 whenever the component blocks (is in its off-state). The component blocks when a voltage is applied between the drain terminal 61 and the source terminal 51S, that biases the pn-junction in its reverse direction, and when gate electrode 92 via gate terminal G is controlled to prevent a conducting channel in the body zone 5 between source zone 91 and drift zone 1. Source terminal 51S contacts both source zone 91 and body zone 5 via source electrode 91.

The MOSFET conducts (is in its on-state) when gate electrode 92 is controlled to generate an inversion channel along gate dielectric zone 93 between source zone 91 and drift zone 1. In an n-type MOSFET a positive potential relative to the source potential is to be applied to the gate electrode 92 in order to generate the inversion channel.

In the on-state drift control zone 3 is biased so as to effect a conducting channel in the drift zone 1 along the drift control zone dielectric 2 between the drain and body zones 6, 5. Referring to FIGS. 6 and 7 drift control zone 3 is coupled to drain zone 6 via a rectifying element 8, such as a diode. The rectifier element is connected such that in the on-state of the component drift control zone 3 is not discharged to drain zone 6. The operating principle of a MOSFET according to FIGS. 6 and 7 will now be explained for an n-type MOSFET having an n-doped drift zone.

In the on-state the drift control zone 3 is charged to a potential that is positive relative to the potential of the drift zone 1, so that an accumulation channel is generated in the drift zone 1 along drift control zone dielectric 2. The charge required in the drift control zone 3 is, for example, provided from gate terminal G via a second rectifier element 44. The second rectifier element is connected such that discharging of the drift control zone 3 in the direction of the gate terminal is prevented.

For storing the electrical charge, that is required in the drift control zone 3 in the on-state of the component, during the off-state an optional capacitor is connected between the drift control zone 3 and a terminal for a reference potential, such as the source terminal S. The capacitor helps to keep switching losses of the component low, since the drift control zone charge does not have to be provided with each switching process.

According to one embodiment the capacitor includes the barrier 4, that has been explained with reference to FIG. 4 as a capacitor dielectric, and further includes a first electrode and second electrode 44. In the embodiment the first electrode is the drift control zone 3. Optionally, an additional semiconductor zone 31 (illustrated in dashed lines) acts as the first electrode. In an n-type MOSFET semiconductor zone 31 is, for example, a p-doped zone, while drift control zone 3 may be an n-doped zone. The second electrode 44 is, for example a metal electrode.

It is to be understood that the features of the various exemplary embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor component, comprising:
a first semiconductor region and a second semiconductor region;
an oxide layer arranged between the first and second semiconductor region, first semiconductor region and the oxide layer forming a first semiconductor-oxide interface, and second semiconductor region and the oxide layer forming a second semiconductor-oxide interface; and
wherein the oxide layer has a chlorine concentration, the chlorine concentration having a first maximum in the region of the first semiconductor-oxide interface, and having a second maximum in the region of the second semiconductor-oxide interface.

2. The semiconductor component of claim 1, wherein the chlorine concentration in the first and second maximum region is between 10¹⁹ cm⁻³ and 2·10²¹ cm⁻³.

3. The semiconductor component of claim 1, wherein the chlorine concentration has a minimum less than the first maximum and the second maximum in between the first semiconductor-oxide interface and the second semiconductor-oxide interface, the chlorine concentration in the minimum being between 10¹⁵ cm⁻³ and 10¹⁸ cm⁻³.

4. The semiconductor component of claim 1, wherein the oxide layer has a thickness, the thickness being the dimension of the oxide layer between the first and second semiconductor-oxide interface, the thickness being between 10 nm and 1 μm.

5. The semiconductor component of claim 1, wherein the first and second semiconductor regions are silicon regions.

6. The semiconductor component of claim 1, wherein the first and second semiconductor regions are monocrystalline semiconductor regions.

7. A semiconductor component, comprising:
a first semiconductor region and a second semiconductor region;
an oxide layer arranged between the first and second semiconductor region, first semiconductor region and the oxide layer forming a first semiconductor-oxide interface, and second semiconductor region and the oxide layer forming a second semiconductor-oxide interface; and
wherein the oxide layer has a chlorine concentration, the chlorine concentration having a first maximum in the region of the first semiconductor-oxide interface, and having a second maximum in the region of the second semiconductor-oxide interface.
wherein the first and second semiconductor region and the oxide layer are arranged in a semiconductor body having a first surface,
wherein the oxide layer extends to the surface of the semiconductor body, and
wherein a barrier is arranged on the surface and at least partly covers the section of the oxide layer extending to the surface.

8. The semiconductor component of claim 7, wherein the barrier comprises a silicon layer or a -nitride layer.

9. The semiconductor component of claim 7, wherein the barrier comprises a layer stack having at least two layers of different materials.

10. The semiconductor component of claim 9, wherein the barrier comprises at least one oxide layer and at least one nitride layer.

11. The semiconductor component of claim 1, wherein the first and second semiconductor regions are active component regions.

12. A semiconductor component, comprising:
a first semiconductor region and a second semiconductor region;
an oxide layer arranged between the first and second semiconductor region, first semiconductor region and the oxide layer forming a first semiconductor-oxide interface, and second semiconductor region and the oxide layer forming a second semiconductor-oxide interface; and
wherein the oxide layer has a chlorine concentration, the chlorine concentration having a first maximum in the region of the first semiconductor-oxide interface, and having a second maximum in the region of the second semiconductor-oxide interface.
wherein the first semiconductor region forms a drift region and the second semiconductor regions forms a drift control region of the semiconductor component, and
wherein the semiconductor component further comprises:
a drain region adjoining the drift region and being coupled to the drift control region via a rectifier element;
at least one control structure being arranged distant to the drain region.

13. The semiconductor component of claim 12, wherein the control structure comprises:
a source zone;
a body zone arranged between the source zone and the drift zone; and
a gate electrode arranged adjacent to the body zone and being insulated from the body zone by a gate dielectric.

14. The semiconductor component of claim 13, further comprising:
a capacitor connected to the drift control region.

15. The semiconductor component of claim 14, wherein the capacitor is connected between the drift control region and one of the source and body region.

16. A method for forming a semiconductor component, the method comprising:
providing a semiconductor body having a first surface;
forming at least one trench extending from the surface into the semiconductor body, the trench having trench surfaces; and
forming an oxide layer in the trench by thermally oxidizing the semiconductor body at the trench surfaces in the presence of chlorine.

17. The method of claim 16, wherein the semiconductor body at least in those regions in which the at least one trench is formed is made of a monocrystalline semiconductor material.

18. The method of claim 17, wherein the semiconductor material is silicon.

19. The method of claim 16, wherein chlorine is present during the complete thermal oxidation process.

20. The method of claim 16, wherein chlorine is present temporarily during the thermal oxidation process.

21. The method of claim 20, wherein no chlorine is present during a starting period of the oxidation process, and wherein chlorine is present after the starting period.

22. The method of claim 16, wherein a chlorine containing gas has a concentration of between 1% and 8%, or between 2% and 8%, of a process gas in the oxidizing ambient.

23. The method of claim 22, wherein the concentration of the chlorine containing gas varies during the oxidation process.

24. The method of claim 16, further comprising:
forming a barrier on the first surface above the oxide layer, including forming at least one nitride layer.

25. A method for forming a semiconductor component, the method comprising:
providing a first semiconductor body having a first surface;
forming an oxide layer having a chlorine concentration on the first surface by thermally oxidizing the first semiconductor body along the first surface in the presence of chlorine, the first semiconductor body and the oxide layer forming a first semiconductor-oxide interface;
bonding a second semiconductor body on the oxide layer, the second semiconductor body and the oxide layer forming a second semiconductor-oxide interface;
heating the arrangement including the first and second semiconductor body and the oxide layer, temperature and duration of the heating process being selected such that a first and a second maximum of a chlorine concentration of the oxide layer occurs in the region of the first and second semiconductor-oxide interface.
